(19) United States
(12) Patent Application Publication
(10) Pub. No.: US 2009/0308317 A1
(43) Pub. Date: Dec. 17, 2009

(54) CARRIER WITH DEPOSITION SHIELD

(75) Inventors: Hiroshi Sone, Sagamihara-shi (JP); Shinya Houman, Tokyo (JP); Naoyuki Nozawa, Tokyo (JP); Yoshiro Hasegawa, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/468,887

(22) Filed: May 20, 2009

Related U.S. Application Data
(63) Continuation of application No. PCT/JP2008/061021, filed on Jun. 17, 2008.

(51) Int. Cl. C23C 14/56; C23C 14/50

(52) U.S. Cl. 118/719; 118/729

(57) ABSTRACT

The peeling-off of a deposited film caused by a carrier is restrained, and the exchange period of the carrier is prolonged. In a carrier 1 including a slider 7 having a mechanism for conveying a substrate holder 3 that supports a substrate 2, a deposition shield 20a, 20b that can cover the substrate holder 3 and has an opening equivalent to or larger than the substrate 2 on which a film is formed is installed on both surfaces of the substrate holder 3. At this time, the substrate holder 3, supporting claws 4, and fixing parts 6 are arranged so as to be hidden by the deposition shield 20. In a film forming chamber, to form a predetermined film on the substrate 2, the carrier 1 covered by the deposition shield 20 is exposed to a plasma space in the film forming chamber, and the film is formed. The deposition of film onto the substrate holder 3, the supporting claws 4, and the fixing parts 6 that are covered by the deposition shield 20 can be restrained. Therefore, the peeling-off of film due to the deflection of claw or the peeling-off of film from the acute angle part of the fixing part 6 and the like is restrained, by which the exchange period of the carrier 1 can be prolonged.

### CROSS-REFERENCES TO RELATED APPLICATIONS

This application is a continuation application of International Application No. PCT/JP2008/061021, filed on Jun. 17, 2008, the entire contents of which are incorporated by reference herein

### TECHNICAL FIELD

The present invention relates to a carrier having supporting claws for supporting a substrate, which is used in a film forming apparatus that performs predetermined processing on the surface of the substrate.

### BACKGROUND ART

A film is often formed on the surfaces of various substrates. As shown in FIGS. 1 and 13, to hold a substrate 2 at a predetermined position in a film forming chamber in which a film is formed, an apparatus for forming a film has a carrier 1 formed by a substrate holder 3 having supporting claws 4 and fixing parts 6, and a slider 7 having a mechanism for conveying the substrate holder. A film should inherently be deposited on the substrate 2 only, but is deposited on the carrier 1 too. Some film formed in this manner has a high stress, and is deposited thick on the carrier 1, especially the supporting claws 4 for supporting the substrate 20 To remove the deposits, the substrate holder 3 is removed from the slider 7, being disassembled and cleaned for reuse, and then is used again (refer to FIG. 13).

Published Japanese translations of PCT international publication for patent applications, WO 01/056758 describes a vertical-type carrier. In this configuration of carrier, the supporting claws for supporting the substrate and the fixing parts for fixing the supporting claws are exposed.
Patent Document 1: WO 01/056758

Further, conventionally, by arranging a shield 13 fixed to a film forming chamber 10 between a film forming source 11 in the film forming chamber 10 and a carrier 12 as shown in FIG. 2, the deposition of film onto the carrier 12 has been reduced However, a clearance has been provided to prevent the carrier from coming into contact with the shield when the carrier is conveyed into the film forming chamber, so that a film has been deposited on the supporting claws 4 and the fixing parts 6 too (refer to National Publication of International Patent Application No. 2002-512658).
Patent Document 2: National Publication of International Patent Application No. 2002-512658

Besides the substrate holder 3 of the carrier 1, there also exists a substrate supporting holder 18 in which supporting claws 17 are incorporated in a substrate holder 16 to a position near a substrate 15 as shown in FIG. 3. In this substrate supporting holder 18, the tip end parts of supporting claws for attaching and detaching the substrate are exposed. Also, the fixing parts and the like of the supporting claws have an exposed construction, so that a film has been deposited on these parts (refer to National Publication of International Patent Application No. 2006-517324).
Patent Document 3: National Publication of International Patent Application No. 2006-517324

### DISCLOSURE OF THE INVENTION

In the carrier 1 shown in FIGS. 1 and 13, since the supporting claws 4 and the fixing parts 6 are exposed, when a film is formed on the substrate 2, the film is deposited on the supporting claws 4 and the fixing parts 6. If continuous processing is performed a plurality of times, the film peels off due to the deflection of claw, or the film peels off from the acute angle part of the fixing part, which causes particles.

Even in the substrate supporting holder 18 in which the supporting claws 17 are incorporated in the substrate holder 16 to the position near the substrate 15 as shown in FIGS. 3A and 3B, or in the method in which the shields 13 fixed to the film forming chamber 10 are arranged at positions near the carrier 12 in the film forming chamber 10 as shown in FIG. 2, a film is still deposited on the tip ends of supporting claws and the fixing parts. Therefore, particles are produced similarly for the above-described reason.

If the particles stick to the surface of the substrate, local abnormality in film thickness occurs. For an information recording disc such as a hard disc, the local abnormality in film thickness easily produces a defect such as a defective sector

The term “sector” means a minimum recording unit on a rotating disc called a platter in the hard disc. If the magnetism of this sector weakens extremely, the recorded magnetic information becomes incapable of being read and written. The cause for this is not limited to the deterioration of magnetism. The above-mentioned abnormality in film thickness may cause the same trouble. The sector incapable of being read and written is called a defective sector.

Further, for the recent information recording disc, the sector has decreased in size to improve the recording density. Therefore, even minor abnormality in film thickness (for example, the formation of a protrusion) easily causes the defective sector.

For the reason as described above, in the conventional film forming apparatus, a carrier subjected to continuous processing a plurality of times has inevitably been replaced with a new one or a carrier having been cleaned for reuse.

The present invention has been made to solve the above described particle problem, and also an object thereof is to prolong the exchange period of a carrier.

A deposition shield of the present invention has a size capable of covering all of a substrate holder, supporting claws, and fixing parts, and has an opening equivalent to or larger than a substrate on which a film is formed. The deposition shield can be installed on both surfaces or one surface of the substrate holder.

The deposition shield is connected to a slider, which has a mechanism for conveying the substrate holder, together with the substrate holder, and is put into a carrier stocker and a film forming chamber.

The deposition shield has hook-like elements for fixing. By hooking the elements to rectangular holes in the substrate holder, the deposition shield is fixed to the substrate holder 3. Also, other fixing methods using screws, a magnet, or the like can also be used.

To relax the stress of film, the deposition shield is preferably configured, if possible, so that an acute angle construction is excluded and an assembled configuration using different materials is avoided. Also, by selecting a material having high thermal conductivity, the film stress due to thermal expansion at places other than a place near a heat input part can be relaxed.

Further, to make the peeling-off of a film deposited on the deposition shield difficult, the surface is made coarse by sandblasting or thermal spraying, by which an effect that a physical adhesion force of the deposited film is increased is expected. For the carrier as well, the same effect can be expected.

A deposition shield attaching/detaching apparatus includes a robot chamber in which a deposition shield attaching/detaching robot is provided to exchange the deposition shield, a carrier conveyance chamber, and a cover storage chamber in which a storage area for storing the deposition shields is arranged.

By the carrier 1 and the deposition shield 20 of the present invention, the peeling-off of the deposited film caused by the carrier 1 can be restrained, and the exchange period of the carrier 1 can be prolonged Also, by using a deposition shield attaching/detaching apparatus shown in FIG. 5, the deposition shield 20 can be attached and detached without destroying a vacuum state. Therefore, a substance exerting an adverse influence on the substrate 2, such as particles produced by the exposure of the carrier 1 to the atmosphere, can be restrained.

### BRIEF DESCRIPTION OF THE DRAWINGS

FIG. 1 is a front view of a conventional carrier;

FIG. 2 is a sectional view of a conventional film forming chamber and carrier;

FIG. 3A is a front view of a conventional substrate supporting holder in which supporting claws are incorporated;

FIG. 3B is an enlarged view of FIG. 3A;

FIG. 4A is a side view of a carrier and a deposition shield in accordance with an embodiment;

FIG. 4B is a front view of the carrier and the deposition shield shown in FIG. 4A;

FIG. 5 is an enlarged view of a deposition shield attaching/detaching apparatus in accordance with the present invention;

FIG. 6 is a side sectional view of the deposition shield attaching/detaching apparatus shown in FIG. 5;

FIG. 7 is a plan view of a film forming apparatus for manufacturing an information recording disc in accordance with an embodiment of the present invention;

FIG. 8 is a plan view of a deposition shield attaching/detaching apparatus connected to a film forming apparatus;

FIG. 9 is a plan view of a deposition shield attaching/detaching apparatus placed between a substrate load chamber and a substrate unload chamber, showing another configuration of a film forming apparatus;

FIG. 10 is a plan view showing a state in which a deposition shield attaching/detaching apparatus (vacuum attaching/detaching) is arranged in connection with a carrier stocker, showing still another configuration of a film forming apparatus;

FIG. 11 is a plan view showing a state in which a deposition shield attaching/detaching apparatus (atmospheric attaching/detaching) is arranged in connection with a carrier stocker, showing yet another configuration of a film forming apparatus;

FIG. 12 is a side sectional view showing an arrangement in which a carrier conveyance chamber is used as a substrate holder cleaning chamber;

FIG. 13 is a perspective view of a conventional substrate holder;

FIG. 14A is a perspective view of a substrate holder in accordance with the present invention; and

FIG. 14B is a perspective view showing a state in which a deposition shield of the substrate holder shown in FIG. 14A is disassembled.

### DESCRIPTION OF REFERENCE NUMERALS

1 carrier
2 substrate
3 substrate holder
4 supporting claw
5 rectangular hole
6 fixing part
7 slider
10 film forming chamber
11 film forming source
12 carrier
13 shield
15 substrate
16 substrate holder
17 supporting claw
18 substrate holder
20a, b deposition shield (before assembly)
21 deposition shield opening
22 fixture
23 carrier
30 deposition shield attaching/detaching apparatus
31 deposition shield attaching/detaching robot
32 robot chamber
33 deposition shield stocker cassette
34 cover storage chamber
35 carrier conveyance chamber
36 vacuum sluice valve
37 atmosphere sluice valve
38 vacuum pump
39 substrate
40 vacuum chamber sluice valve
41 substrate load chamber
42 substrate unload chamber
43, 44, 45, 46 direction change chamber
47 carrier stocker
50 deposition shield attaching/detaching chamber
51 substrate load chamber
52 substrate unload chamber
53 substrate
54 carrier
60 deposition shield attaching/detaching chamber
61 film forming chamber
62 carrier stocker
63 deposition shield attaching/detaching robot
70 deposition shield attaching/detaching chamber
71 film forming chamber
72 carrier stocker
73 waiting chamber
74 evacuating mechanism
80 carrier conveyance chamber
81 electrode driving rod
82 substrate holder
83 matching device
84 high frequency power source
85 transmission line
86 high frequency introducing rod
87 electrode spring
88 gas
90 direction change chamber
91 deposition shield attaching/detaching apparatus

### BEST MODES FOR CARRYING OUT THE INVENTION

An embodiment of the present invention will now be described. In the description below, explanation is given by taking a film forming apparatus for manufacturing an information recording disc as one example of film forming apparatus.

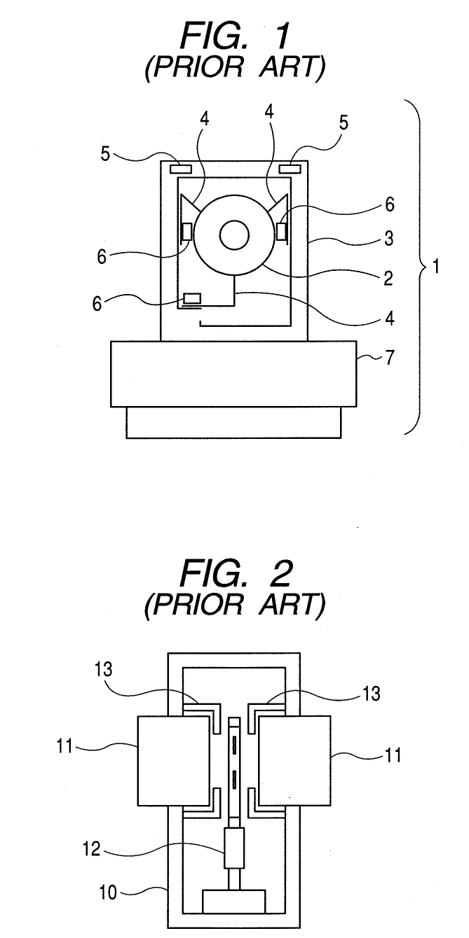

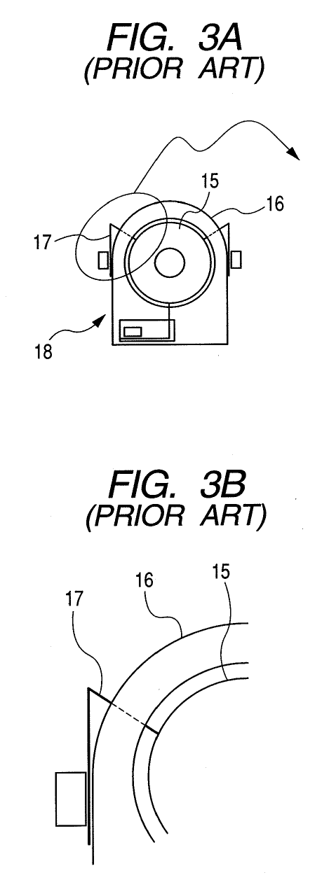

FIG. 7 is a plan view showing the general configuration of a film forming apparatus in accordance with an embodiment of the present invention In the apparatus of this embodiment, a plurality of vacuum chambers are arranged in series along a rectangular outline. Each of the vacuum chambers is a vacuum vessel that is evacuated by a dedicated or multiple-used exhaust system. In the boundary part of each vacuum chambers a vacuum chamber sluice valve 40 is arranged In the aforementioned film forming apparatus, a substrate 2 shown in FIG. 1 is conveyed while being held by a carrier 1. A rectangular travel path is provided in the plurality of vacuum chambers arranged in series, and a moving mechanism for moving the carrier 1 along this travel path is provided. The carrier 1 is conveyed in the chambers by this moving mechanism while holding the substrate 2.

Among the plurality of vacuum chambers, two vacuum chambers arranged on one side of the rectangle are used as a substrate load chamber 41 in which the substrate 2 is mounted on the carrier 1 and a substrate unload chamber 42 in which the substrate 2 is withdrawn from the carrier 1. Of the rectangular travel path, a part between the substrate load chamber 41 and the substrate unload chamber 42 is used as a return travel path for returning the carrier 1 from the substrate unload chamber 42 to the substrate load chamber 41.

Also, other vacuum chambers are used as vacuum chambers in which the substrate 2 is subjected to various processing. The vacuum chambers at the corners of the rectangle are used as direction change chambers 43, 44, 45 and 46 each provided with a direction change mechanism, in which the conveyance direction of the carrier 1 is changed 90 degrees.

A carrier stocker 47, in which new carriers and carriers having been cleaned for reuse can be stored, and the carrier on which a film is deposited in the film forming apparatus can be exchanged, is connected to the direction change chamber. By the carrier stocker 47, the carrier 1 can be exchanged without halting the production.

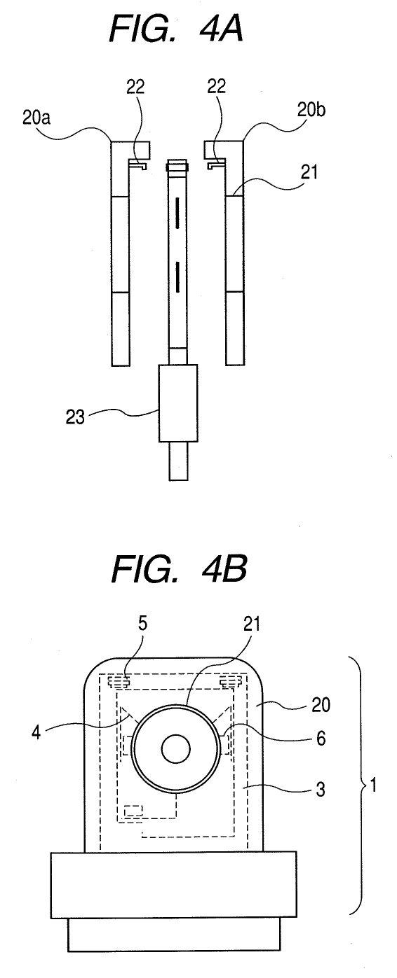

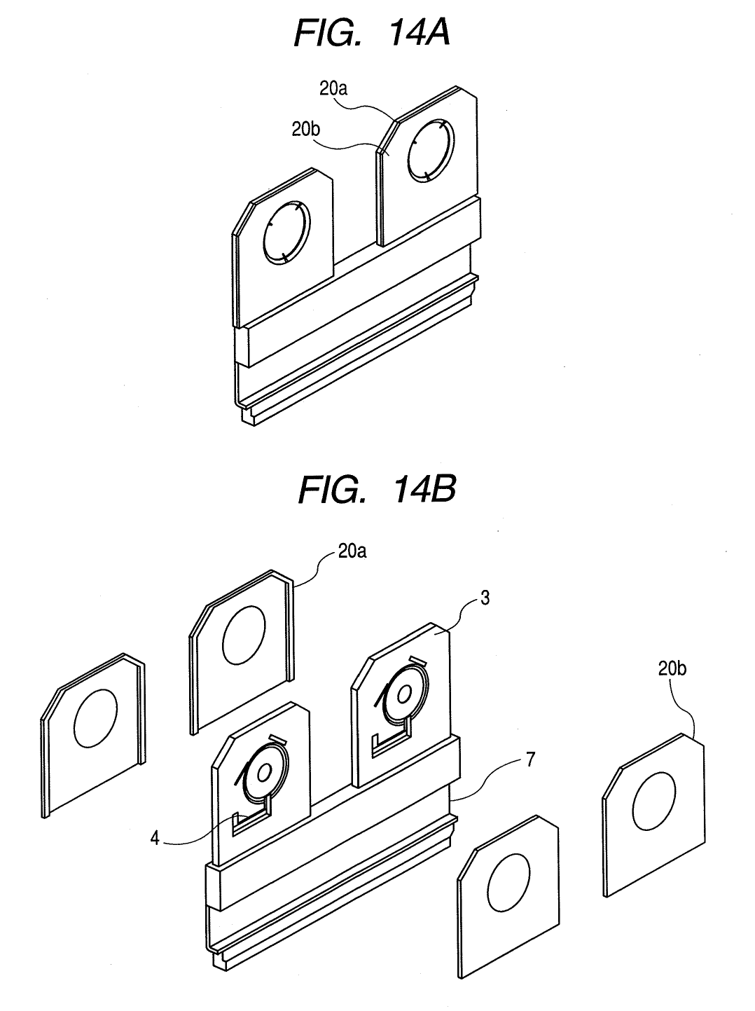

FIGS. 4A and 4B are side view and a front view, respectively, of a carrier 23 and a deposition shield 20 in accordance with the embodiment of the present invention. As shown in FIG. 1, the carrier 23 has a substrate holder 3, a slider 7 for conveying the substrate holder 3, supporting claws 4, and fixing parts 6, and the substrate holder 3 is formed with rectangular holes 5 or the like for installing the deposition shields 20a and 20b. Each of the deposition shields 20a and 20b has fixtures 22, and is fixed to the substrate holder 3 by the fixtures 22. The method for fixing the deposition shields 20a and 20b to the substrate holder 3 is not subject to any special restriction; for example an inserting method, a hooking method, and a screwing method can be used. FIG. 14A is a perspective view of the carrier 23 in accordance with a first embodiment of the present invention, and FIG. 14B is a perspective view showing a state in which the deposition shields 20a and 20b are removed. The substrate holder 3 is sandwiched between the two deposition shields 20a and 20b.

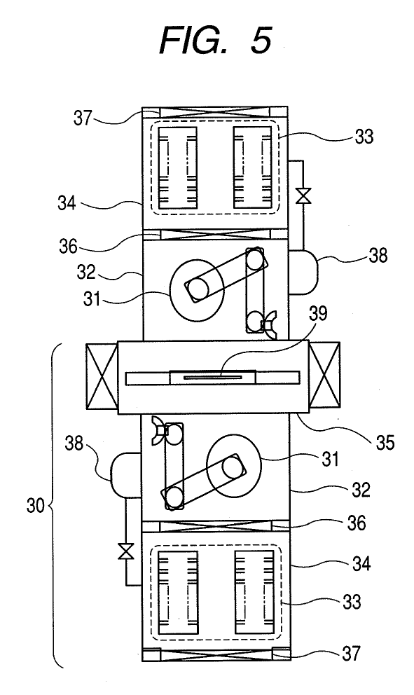

FIG. 5 shows a deposition shield attaching/detaching apparatus 30 in accordance with the present invention. The deposition shield attaching/detaching apparatus 30 has a robot chamber 32 in which a deposition shield attaching/detaching robot 31 is provided to exchange the deposition shield 20, a cover storage chamber 34 in which a storage area 33 is arranged to store the deposition shields, and a carrier conveyance chamber 35, and also has a vacuum sluice valve 36, an atmosphere sluice valve 37, and a vacuum pump 38. Also, the deposition shield attaching/detaching apparatus 30 can be arranged on both surfaces with respect to a substrate 39 with the carrier conveyance chamber 35 being held therebetween.

By the configuration shown in FIG. 5, the deposition shield can be attached and detached in a vacuum which achieves an effect that a substance exerting an adverse influence on the substrate 2, such as particles produced by the exposure of the carrier 1 to the atmosphere can be restrained.

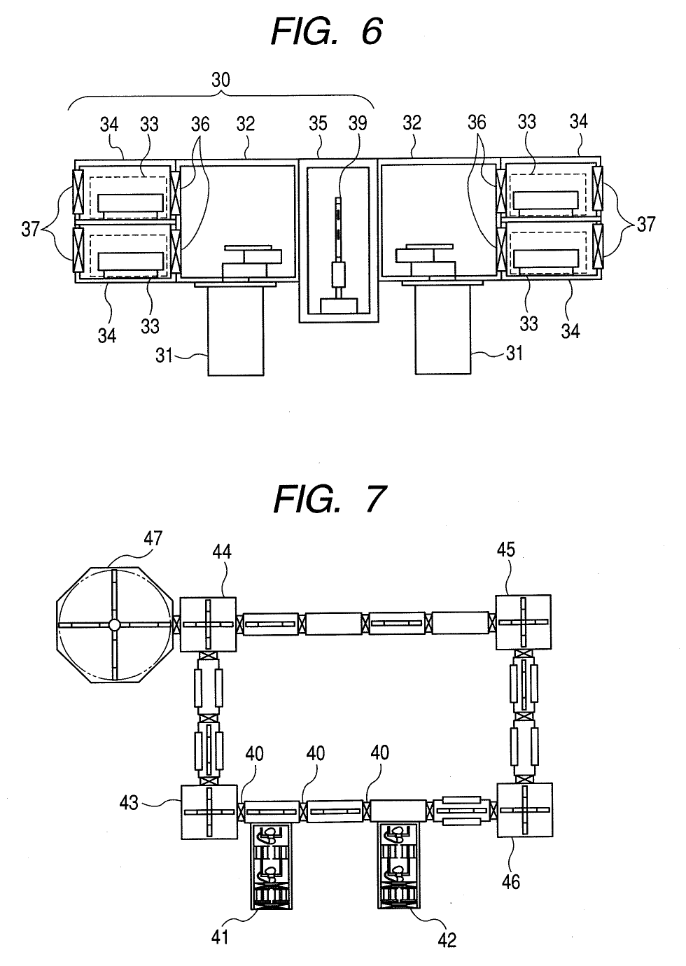

FIG. 6 is a side sectional view of the deposition shield attaching/detaching apparatus shown in FIG. 5. The cover storage area 33 for storing the deposition shields for exchange which area is provided in the deposition shield storage chamber 34 can also be arranged vertically or transversely. FIG. 6 shows an example in which the cover storage areas 33 are arranged vertically.

By the configuration shown in FIG. 6 the deposition shield before exchange and the deposition shield after exchange can be stored separately which achieves an effect that the deposition of particles onto the deposition shield before exchange can be reduced.

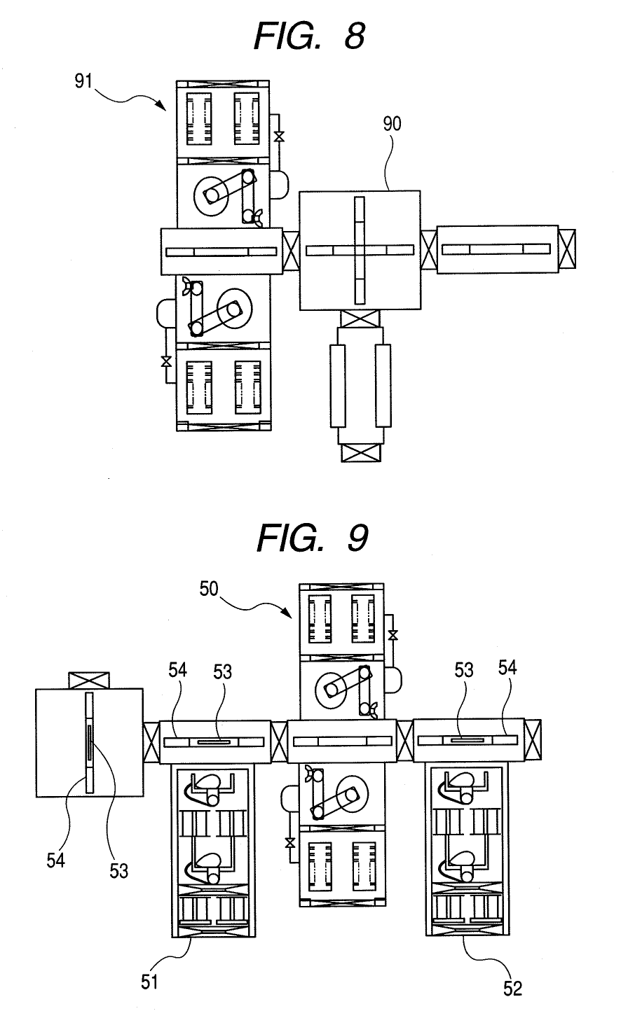

FIG. 8 shows an arrangement in which a deposition shield attaching/detaching apparatus 91 is connected to a direction change chamber 90 of the film forming apparatus. By the arrangement shown in FIG. 8, an effect that the deposition shield attaching/detaching apparatus 91 can be used as a load-lock chamber is achieved.

FIG. 9 shows another arrangement. By arranging a deposition shield attaching/detaching apparatus 50 between a substrate supply apparatus 51 and a substrate delivery apparatus 52, the deposition shield 20 can be attached and detached in the state in which a substrate 53 is absent on a carrier 54.

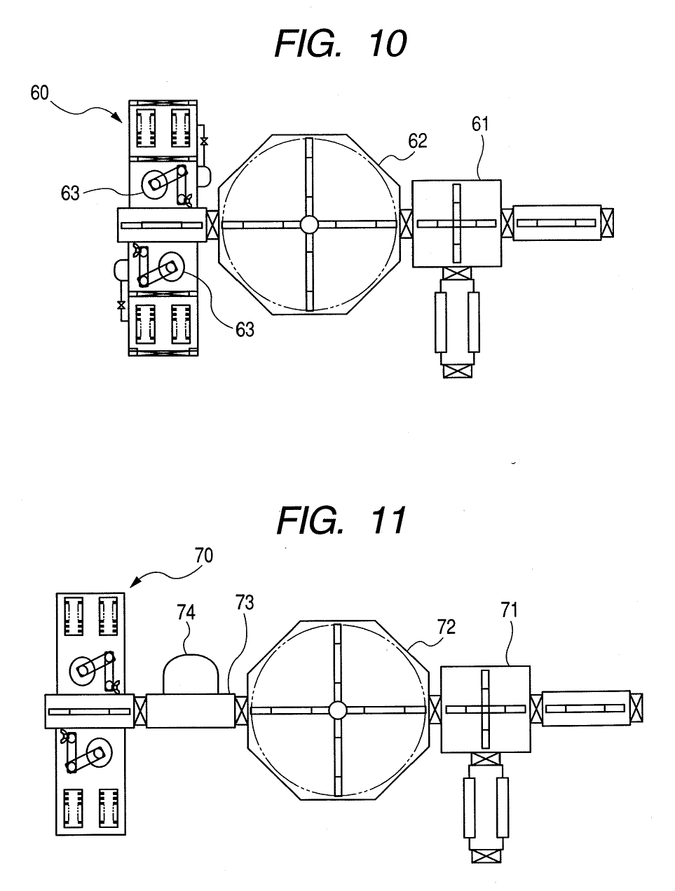

FIG. 10 shows still another arrangement. By arranging a deposition shield attaching/detaching apparatus 60 in connecting with a carrier stocker 62 provided on a film forming apparatus 61, the carrier can be exchanged without disturbing the film forming state in the film forming apparatus 61 and the tact system. In the case where a film is deposited on the deposition shield 20 installed on the carrier in the film forming apparatus 61, the carrier on which the film has been deposited can be exchanged for a carrier having been arranged in advance in the carrier stocker 62. Also, the film-deposited carrier stored in the carrier stocker 62 is conveyed to the deposition shield attaching/detaching apparatus 60, and the deposition shield 20 is exchanged by a deposition shield attaching/detaching robot 63. The exchanged cover is stored again in the carrier stocker 62 together with the carrier. Thereby, the film forming process can be continued without exchanging the carrier having parts exerting an influence directly on the substrate, such as supporting claws.

FIG. 11 shows yet another arrangement. A deposition shield attaching/detaching apparatus 70 is provided on a carrier stocker 72 provided on a film forming apparatus 71 via a waiting chamber 73 having an evacuating mechanism 74, by which the deposition shield can be attached and detached in the atmosphere. Therefore, the deposition shield attaching/detaching apparatus 70 can be manufactured at a relatively low cost. Also, the attaching/detaching operation in this state need not be automated by using a robot or the like, and can be performed manually.

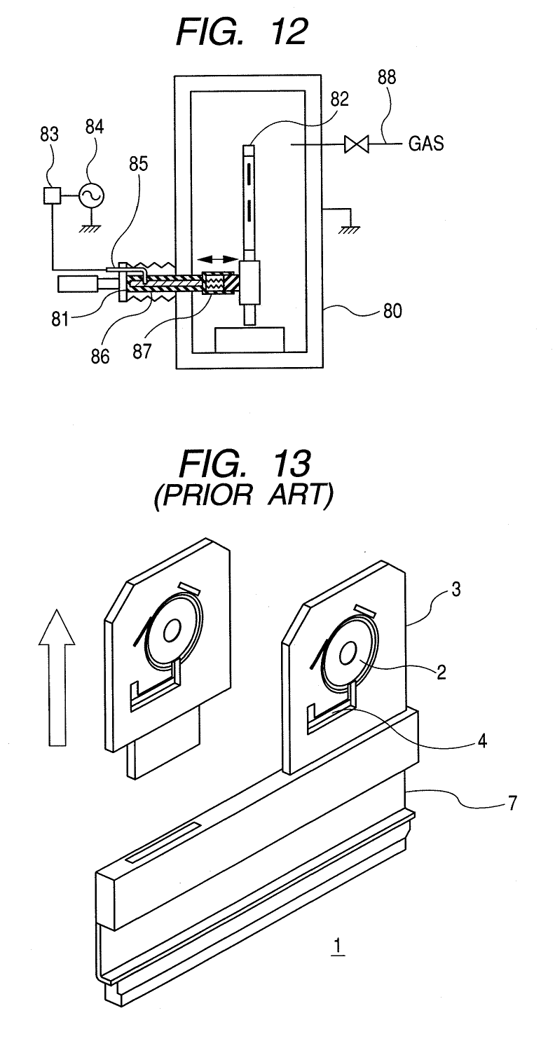

FIG. 12 is a side sectional view showing an example in which the carrier conveyance chamber is also used as a substrate processing chambers especially a substrate holder cleaning chamber. A high frequency introduction path 81 is provided in a carrier conveyance chamber 80. The carrier conveyance chamber 80 is evacuated to a predetermined vacuum pressure by an exhaust system provided separately, and that pressure is maintained. Then, the electrode driving rod 81 advances through a predetermined stroke. As a result, a voltage from a high frequency power source 84 is applied to a substrate holder 82 via a transmission line 85, a high frequency introducing rod 86, and an electrode spring 87.

When the high frequency voltage is applied to the substrate holder 82, an electric field is set up between the substrate holder 82 and the wall and the like of the carrier conveyance chamber 80 that is maintained at an installation potential, and high frequency electric discharge is produced in the introduced gas, by which high frequency discharge plasma is formed. At this time, between the plasma and the high frequency power source 84, there exists capacitance caused by a capacitor included in a matching device 83, a not illustrated capacitor provided separately, or the like. When a high frequency electric field is set up in a space, in which the plasma is formed, via the capacitance, electrons and ions in the plasma act on the charge and discharge of capacitance. As a result, due to a difference in the mobility of electrons and ions, a voltage corresponding to a negative current, which is called a self-bias voltage, is generated on the surface of the substrate holder 82.

In the case where argon gas 88 is introduced into the carrier conveyance chamber 80, the ions in the plasma are accelerated by this self-bias voltage, and impinge on the deposited film on the surface of the substrate holder 82 to give an impact to the deposited film. Thereby, the deposited film is subjected to sputter etching, and is removed from the substrate holder 82. Also, in the case where oxygen gas is introduced into the carrier conveyance chamber in place of argon gas, oxygen plasma is generated, and thereby active oxygen is yielded. Due to this active oxygen, the oxygen gas reacts with a protective film formed by carbon or the like, and is discharged by being changed to a gas such as carbon monoxide or carbon dioxide. Thereby, the deposited film is subjected to oxygen ashing, and is removed from the substrate holder 82.

After the sputter etching and ashing have been performed for a predetermined period of time, the operation of the high frequency power source 84 is stopped. Thereafter, the electrode driving rod 81 is driven to separate the electrode spring 87 from the substrate holder 82.

By using the carrier conveyance chamber also as the substrate processing chamber as shown in FIG. 12, the substrate processing chamber can be reduced, which achieves an effect of reducing the foot print.

1. A carrier comprising: a substrate holder having a substrate supporting claw member for supporting a substrate; and a slider for conveying the substrate,
wherein a deposition shield for preventing a film from depositing on the substrate supporting member is provided on the substrate holder.

2. The carrier according to claim 1, wherein the deposition shield is installed on both surfaces or one surface of the substrate holder.

3. The carrier according to claim 1, including an apparatus for attaching and detaching the deposition shield to facilitate exchanging the deposition shield, which apparatus is provided separately.

4. An apparatus for attaching and detaching a deposition shield, comprising: a deposition shield stocker chamber for storing the deposition shield; a robot chamber in which a deposition shield attaching and detaching robot for exchanging the deposition shield is provided; and a carrier conveyance chamber for conveying a carrier mounted with the deposition shield, the carrier comprising a substrate holder having a substrate supporting member for supporting a substrate; the deposition shield installed detachably on the substrate holder to prevent a film from depositing on the substrate supporting member; and a slider for conveying the substrate holder.

5. The apparatus according to claim 4, wherein a separate stocker chamber is used before and after the exchange of the deposition shield, as the deposition-shield stocker chamber.

6. The apparatus according to claim 4, wherein the deposition shield stocker chamber and the robot chamber are provided on one side or both sides in the conveyance direction of the carrier conveyance chamber.

7. The apparatus according to claim 4, wherein the apparatus is connected to a carrier stocker for withdrawing, storing, and delivering the carrier.

8. The apparatus according to claim 4, wherein the apparatus is provided between a substrate load chamber and a substrate unload chamber of an in-line processing apparatus.

9. The apparatus according to claim 6, wherein the apparatus is connected to a waiting chamber having an evacuating/venting mechanism and a carrier conveying mechanism, the waiting chamber being provided between the apparatus and the carrier stocker.

10. The apparatus according to claim 4, wherein the carrier conveyance chamber of the apparatus is also used as a substrate processing chamber.
